(19) United States
(12) Patent Application Publication
(10) Pub. No.: US 2012/0098023 A1
(43) Pub. Date: Apr. 26, 2012

(54) NITRIDE SEMICONDUCTOR LIGHT-EMITTING DEVICE

(75) Inventors: Yufeng Weng, Osaka-shi (JP); Michael Brockley, Oxford (GB)

(73) Assignee: Sharp Kabushiki Kaisha, Osaka-shi (JP)

(21) Appl. No.: 13/317,101

(22) Filed: Oct. 11, 2011

(30) Foreign Application Priority Data
Oct. 20, 2010 (JP) 2010-235496

(51) Int. Cl. H01L 33/62

(52) U.S. Cl. 257/99; 257/E33.062

(57) ABSTRACT

A nitride semiconductor light-emitting device includes at least one n-type semiconductor layer, an active layer and at least one p-type semiconductor layer within a rectangle nitride semiconductor region on a substrate. The n-type semiconductor layer has a partial exposed area, a p-side branch electrode integral with a p-side electrode pad formed on a current diffusion layer formed on the p-type semiconductor layer, an n-side branch electrode integral with an n-side electrode pad formed on the partial exposed area of the n-type semiconductor layer, the p-side and n-side branch electrodes extend parallel to each other along two opposite sides of the semiconductor region, and conditions of 0.3<M/L<1.1 and L<Lₘₐₓ are satisfied; L is the distance between centers of the p-side and n-side electrode pads, M is the distance between the p-side and n-side branch electrodes, and Lₘₐₓ represents a distance between the centers of the p-side and n-side electrode pads.

This nonprovisional application is based on Japanese Patent Application No. 2010-235496 filed on Oct. 20, 2010 with the Japan Patent Office, the entire contents of which are hereby incorporated by reference.

### BACKGROUND OF THE INVENTION

1. Field of the Invention

The present invention is related to a light-emitting device produced utilizing nitride semiconductor (InₓAl_{y}Ga_{1-x-y}N, 0≦x<1, 0≦y<1) and particularly to a nitride semiconductor light-emitting device usable as a high-luminance light source for a backlight of a liquid crystal display device, usual illumination and so forth.

2. Description of the Background Art

In general, a nitride semiconductor light-emitting device includes an n-type nitride semiconductor layer, a nitride semiconductor light-emitting layer and a p-type nitride semiconductor layer successively stacked on a sapphire substrate. The p-type semiconductor layer side and n-type semiconductor layer side are provided with a p-side electrode pad and an n-side electrode pad respectively for connecting to an external power supply. The p-type nitride semiconductor layer usually has a higher sheet resistance as compared to the n-type nitride semiconductor layer. For the purpose of aiding diffusion of electric current in the p-type semiconductor layer, therefore, a transparent electrode layer such as of ITO (indium tin oxide) is formed on almost the entire surface of the p-type semiconductor layer, and the p-side electrode pad is formed on the transparent electrode layer. Namely, the transparent electrode layer transmits light from the light-emitting layer and also functions as a current diffusion layer.

In the case of using an insulative substrate such as a sapphire substrate, the n-side electrode pad cannot be formed on a backside of the substrate. Therefore, the n-type semiconductor layer is partially exposed by etching from the p-type semiconductor layer side, and then the n-side electrode pad is formed on the exposed area. By supplying electric power between the p-side electrode pad and n-side electrode pad, it is thus possible to obtain light emission from the light-emitting layer sandwiched between the p-type semiconductor layer and n-type semiconductor layer.

It is generally known that the operation voltage of the light-emitting device can be increased or decreased by adjusting the distance between the n-side electrode pad and p-side electrode pad. Japanese Patent Laying-Open No. 2008-010840 teaches to improve the uniformity of light emission and reduce the operation voltage in the nitride semiconductor light-emitting device by limiting in a prescribed range the distance between the p-side electrode pad and n-side electrode pad. Here, it should be noted that the semiconductor layers included in the light-emitting device are very thin and thus the distance between the n-side electrode pad and p-side electrode pad is substantially the same as its projected distance on a plane parallel to the semiconductor layers.

Each of Japanese Patent Laying-Open No. 2009-246275 and Japanese Patent Laying-Open No. 2009-253056 discloses a nitride semiconductor light-emitting device wherein there is no or extremely small variation in wavelength of light emission even when its operation current is varied and wherein it is possible to reduce its operation voltage and increase its optical output. Regarding such a light-emitting device, it is taught that the distance between the p-side and n-side electrode pads and also an aspect ratio represented by X/Y should satisfy prescribed conditions, where X and Y denote a long side length and a short side length respectively in a rectangle shape of a plan view of the light-emitting device.

Further, each of Japanese National Patent Publication No. 2003-524295 and Japanese Patent Laying-Open No. 2000-164930 teaches a nitride semiconductor light-emitting device having an n-side electrode pad and a p-side electrode pad on the same side of a substrate, wherein current distribution in the light-emitting device is improved by forming branch portions extended from the n-side electrode pad and p-side electrode pad respectively.

FIG. 8 is a schematic plan view showing an example of the nitride semiconductor light-emitting device disclosed in Japanese National Patent Publication No. 2003-524295. In this example, a p-side electrode pad 19 is formed on a current diffusion layer 18 over a p-type semiconductor layer and then p-side branch electrodes 20a and 20b are extended from the electrode pad. This light-emitting device includes an n-type semiconductor layer having a partial area 23 exposed by etching. An n-side electrode pad 21 is formed on this exposed area 23 and then an n-side branch electrode 22 is extended therefrom.

N-side branch electrode 22 and p-side branch electrodes 20a and 20b are parallel to each other in their regions opposite to each other. In other words, the distance over which current should diffuse from p-side branch electrodes 20a and 20b though current diffusion layer 18 is set to be constant. Similarly, the distance over which current should diffuse from n-side branch electrode 22 is set to be constant. With these branch electrodes, therefore, it is possible to improve uniformity of distribution of current flowing from p-side electrode pad 19 toward n-side electrode pad 21.

In the technical field of the light source for the backlight of liquid crystal TV and for the usual illumination, the LED (light-emitting diode) backlight and LED illumination are now being put to practical uses. The nitride semiconductor light-emitting device for these uses is required to have improved properties (higher optical output, lower operation voltage and less heat generation) in a higher operation current range and be formed with lower costs, as compared to the device for conventional uses. However, if it is attempted to directly apply any of the techniques disclosed in the five above-mentioned Japanese patent documents to the nitride semiconductor light-emitting device, the following problems will be caused.

For example, the current diffusion layer is formed on almost the entire surface of the p-type semiconductor layer in the nitride semiconductor light-emitting device for the above-mentioned uses and thus a part of light emitted from the light-emitting layer is absorbed in the current diffusion layer when the light is emitted to the exterior through the current diffusion layer. Therefore, the current diffusion layer should be made as thin as possible in order to reduce the absorption of light emitted from the light-emitting layer. However, as the current diffusion layer is made thinner, the sheet resistance of the current diffusion layer is increased and then the operation voltage of the device is increased. Further, the increased sheet resistance of the current diffusion layer hinders the sufficient current diffusion function and degrades the uniformity of light emission. Particularly when high current is applied to the light-emitting device, current constriction occurs and then excess heat is generated at the current constriction portion. As a result, there is caused a problem that the proportion of non-emissive recombinations of carriers is increased leading to decrease of the optical output.

In the case that the light-emitting device is provided with the branch electrodes as in Japanese National Patent Publication No. 2003-524295 and Japanese Patent Laying-Open No. 2000-164930, the operation voltage can effectively be reduced and the current diffusion property can effectively be improved. However, if the areas of the branch electrodes are increased, there is caused a problem that the proportion of absorption of light emitted from the light-emitting layer is increased due to shielding by the branch electrodes, leading to decrease of the optical output of the light-emitting device.

### SUMMARY OF THE INVENTION

In view of the above-described problems in the prior-art, an object of the present invention is to improve the current diffusion efficiency in the nitride semiconductor light-emitting device and decrease the operation voltage while obtaining good light emission uniformity and a high optical output even at a high operation current density.

A nitride semiconductor light-emitting device according to the present invention includes at least one n-type semiconductor layer, an active layer and at least one p-type semiconductor layer in this order within a rectangle nitride semiconductor region on an upper surface of a substrate, wherein the n-type semiconductor layer has a partial exposed area formed by etching from the p-type semiconductor layer side, a current diffusion layer is provided on the p-type semiconductor layer, a p-side electrode pad and a p-side branch electrode extending linearly therefrom are provided on the current diffusion layer, an n-side electrode pad and an n-side branch electrode extending linearly therefrom are provided on the partial exposed area of the n-type semiconductor layer, the p-side branch electrode and the n-side branch electrode extend parallel to each other along two opposite sides of the rectangle nitride semiconductor region, and conditions of 0.3<M/L<1.1 and L<Lₘₐₓ are satisfied, where L represents a distance between the center of the p-side electrode pad and the center of the n-side electrode pad, M represents a distance between the p-side branch electrode and the n-side branch electrode parallel to each other, and Lₘₐₓ represents a distance between the center of the p-side electrode pad and the center of the n-side electrode pad when those pads are formed at diagonal positions of the rectangle nitride semiconductor region.

In the meantime, it is preferable to satisfy a condition of 0.6<M/L<0.8 and most preferable to satisfy a condition of M/L=0.7.

The p-side branch electrode is preferably formed near a side of the rectangle nitride semiconductor region and on the inside more than 15 μm from the side. The p-side branch electrode preferably has a width in a range of 4 μm to 8 μm. The current diffusion layer preferably has a thickness in a range of 120 μm to 340 μm.

A side surface of the n-type semiconductor layer preferably has an inclination angle less than 90 degrees with respect to a plane parallel to the layer. The inclination angle is more preferably in a range of 20 degrees to 80 degrees, further preferably in a range of 25 degrees to 50 degrees and most preferably 30 degrees.

Furthermore, the upper surface of the substrate preferably has a periodic uneven structure. With such a periodic uneven structure, it is possible to improve the crystalline quality of the nitride semiconductor layers grown on the substrate and also improve light extraction by the scattering effect of the uneven structure.

According to the present invention as described above, it is possible to decrease the effective sheet resistance of the current diffusion layer by the p-side and n-side branch electrodes parallel to each other and then improve the current diffusion and light emission uniformity in the nitride semiconductor light-emitting device. It is also possible to prevent the current constriction and decrease the operation voltage in the light-emitting device by adjusting the distance between the centers of the p-side and n-side electrode pads. Therefore, it is possible to prevent decrease of optical output of the light-emitting device and suppress heat generation due to the current constriction when the operation current is particularly high.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a schematic plan view of a nitride semiconductor light-emitting device according to an embodiment of the present invention.

FIG. 2 is a schematic cross-sectional view corresponding to the nitride semiconductor light-emitting device of FIG. 1.

FIG. 3 shows schematic plan views of light-emitting devices according to various embodiments of the present invention and a comparative example.

FIG. 4 shows graphs illustrating the relation between the ratio of M/L and the device properties at an operation current of 30 mA in light-emitting devices according to various embodiments of the present invention and a comparative example.

FIG. 5 shows graphs illustrating the relation between the ratio of M/L and the device properties at an operation current of 60 mA in light-emitting devices according to various embodiments of the present invention and a comparative example.

FIG. 6 shows graphs illustrating the relation between the ratio of M/L and the device properties at an operation current of 100 mA in light-emitting devices according to various embodiments of the present invention and a comparative example.

FIG. 7 shows photographs illustrating light-emitting states at a high operation current in light-emitting devices according to an embodiment of the present invention and examples of the prior art.

FIG. 8 is a schematic plan view of a light-emitting device according to the prior art.

### DESCRIPTION OF THE PREFERRED EMBODIMENTS

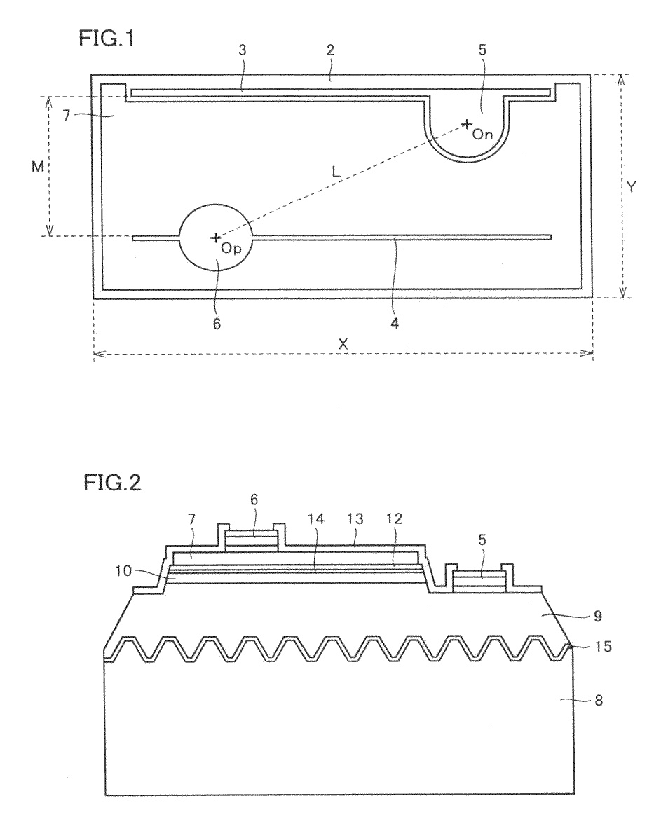

FIG. 1 schematically shows an example of an upper side of a nitride semiconductor light-emitting device according to an embodiment of the present invention and FIG. 2 schematically shows a cross-sectional stacked-layer structure of the light-emitting device of FIG. 1. Incidentally, in the drawings of this application, the length, width, thickness and so forth are arbitrarily changed for the purpose of clarification and simplification of the drawings and do not reflect the actual dimensional relations.

The light-emitting device as shown in FIGS. 1 and 2 can be made as follows. There is first prepared a transparent substrate 8 such as of sapphire having a periodic uneven structure on a main surface thereof. Such a periodic uneven surface structure can serve to reduce dislocation density in nitride semiconductor layers crystal-grown thereon and improve light extraction by scattering effect of the unevenness.

A nitride semiconductor buffer layer 15, an n-type nitride semiconductor layer 9, a nitride semiconductor active layer 10, a p-type clad layer 14, and a p-type nitride semiconductor layer 12 are successively deposited on substrate 8 by MOCVD (metalorganic chemical vapor deposition).

A transparent electrode layer 7 such as of ITO serving as a current diffusion layer is formed on p-type semiconductor layer 12 by sputtering for example. On the other hand, a partial exposed area 2 is formed in n-type semiconductor layer 9 by etching from the side of transparent electrode layer 7.

Thereafter, a p-side electrode pad 6 and p-side branch electrode 4 are formed on transparent electrode layer 7, while an n-side electrode pad 5 and n-side branch electrode 3 are formed on partial exposed area 2 of n-type semiconductor layer 9. These p-side branch electrode 4 and n-side branch electrode 3 are formed parallel to each other.

Further, a protective film 13 such as of SiO₂ is formed on the upper side of the light-emitting device. This protective film 13 includes openings for exposing at least part of n-side electrode pad 5 and at least part of p-side electrode pad 6.

In the meantime, it is preferable that side surfaces of n-type semiconductor layer 9 have an inclination angle less than 90 degrees with respect to a plane parallel to the layer so as to easily emit light from light-emitting layer 10 to the exterior. Such an inclined surface can be formed by etching and the inclination angle can be controlled by selecting etching conditions (kind of resist, kind of etching solution, etching time, etc.).

In order to efficiently extract light from light-emitting layer 10 to the exterior of the light-emitting device, the inclination angle of the side surfaces of n-type semiconductor layer 9 is preferably in a range of 20 degrees to 80 degrees, more preferably in a range of 25 degrees to 50 degrees, and most preferably about 30 degrees. Here, the inclination angle less than 20 degrees is not preferable because a very long etching time is required, and further reduction of the inclination angle is not preferable because the area of p-type semiconductor layer 12 is drastically decreased. On the other hand, when the inclination angle is more than 80 degrees, it is not possible to significantly improve the light extraction efficiency.

In the light-emitting device according to the present invention, as shown in FIG. 1, a condition of 0.3<M/L<1.1 is satisfied, where L represents a distance between the center Op of p-side electrode pad 6 and the center On of n-side electrode pad 5, while M represents a distance between p-side branch electrode 4 and n-side branch electrode 3 parallel to each other. Here, when both electrode pads 6 and 5 are formed at opposite diagonal positions of the rectangle semiconductor region, the distance between the centers of both the electrode pads becomes the maximum Lₘₐₓ, leading to the highest operation voltage of the light-emitting device. Therefore, the light-emitting device according to the present invention should also satisfy a condition of L<Lₘₐₓ.

More specifically, when the operation current of the light-emitting device is in a current density range higher than 90 A/cm², it is preferable to satisfy a condition of 0.6<M/L<0.8 and most preferably to satisfy a condition of M/L of about 0.7.

If distance L between the centers of p-side electrode pad 6 and n-side electrode pad 5 is reduced to deviate from the condition of 0.3<M/L<1.1, there is a possibility that the current in the light-emitting device is constricted between both electrode pads 6 and 5 and then the optical output of the light-emitting device is reduced by increase of light absorption due to the electrode pads and increase of non-emissive recombinations of carriers due to heat generation.

Incidentally, while the present invention is effective irrespective of the aspect ratio X/Y where X and Y represent one side and the other side of the rectangle semiconductor region respectively, the effect of the present invention becomes more significant as the aspect ratio X/Y is increased.

In the light-emitting device according to the present invention, it is also possible to uniformly distribute light emission over the entire surface of the light-emitting device chip even at a high operation current density of 136 A/cm² (injection current 150 mA; injection area 1.10×10⁻³ cm²) for example. Namely, in the light-emitting device according to the present invention, it is possible to improve the diffusion efficiency of injected current and decrease the operation voltage while obtaining uniformity of light emission and a high optical output even with high current density operation (higher than 90 A/cm²), and it is also possible to improve the heat dissipation property of the light-emitting device even with the high current density operation.

While some embodiments of the present invention will more specifically be explained together with comparative examples in the following, it goes without saying that the present invention is not limited to those embodiments.

### Embodiment 1

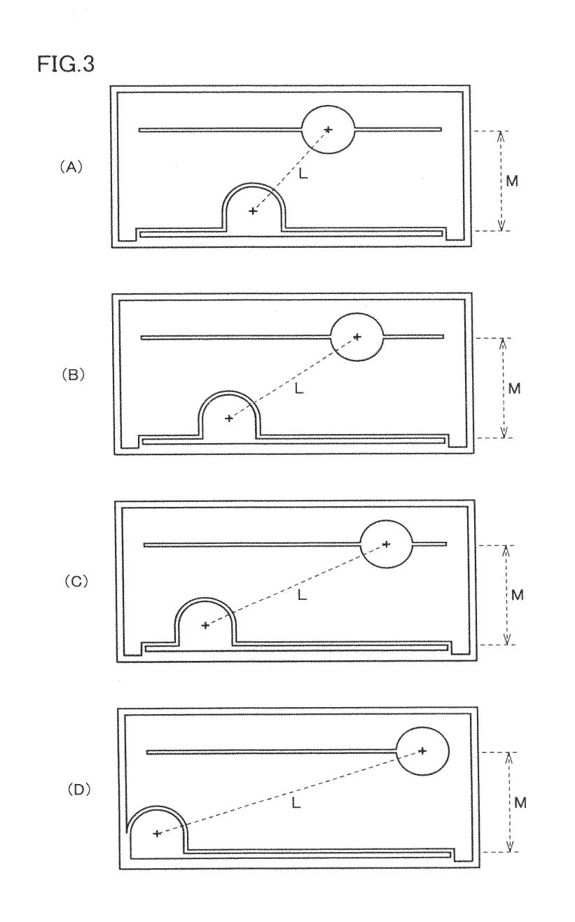

A light-emitting device similar to that schematically illustrated in FIGS. 1 and 2 is produced in Embodiment 1 of the present invention. FIG. 3(A) shows a schematic plan view of the light-emitting device according to this Embodiment 1.

In the light-emitting device of Embodiment 1, as schematically shown in FIG. 2, an n-type nitride semiconductor layer 9 was deposited on a sapphire substrate 8 having a main surface of a (0001) plane orientation with an intervening AlN buffer layer 15 therebetween. This n-type semiconductor layer 9 includes a GaN underlayer of 9 μm thickness and Si-doped n-type GaN contact layer of 2 μm thickness (carrier concentration: about 6×10¹⁸ cm⁻³) deposited at a substrate temperature of about 1000° C.

A nitride semiconductor active layer 10 was deposited on n-type semiconductor layer 9. This active layer 10 has a multi-quantum-well structure in which an n-type In_{0.15}Ga_{0.85}N quantum-well layer of 3.5 nm thickness and an Si-doped GaN barrier layer of 6 nm thickness were deposited six times repeatedly at a substrate temperature of about 890° C.

An Mg-doped p-type Al_{0.2}Ga_{0.8}N upper clad layer 14 (carrier concentration: about 2×10¹⁹ cm⁻³) was deposited on light-emitting layer 10 and then an Mg-doped p-type AlGaN contact layer 12 (carrier concentration: 5×10¹⁹ cm⁻³) was deposited thereon.

An ITO transparent electrode layer 7 of 180 nm thickness was formed on p-type GaN contact layer 12 by sputtering. Sheet resistance of this ITO layer 7 was about 200 Ω/□. After formation of ITO transparent electrode layer 7, a first annealing was conducted at 600° C. for 10 minutes in a mixed gas atmosphere of 2% oxygen and 98% nitrogen so that the transmissivity of ITO transparent electrode layer 7 was increased to 94% for light of 450 nm wavelength. After the first annealing, ITO transparent electrode layer 7 was once exposed to the ambient air and returned into the furnace, and then a second annealing was conducted at 500° C. for 5 minutes in a vacuum atmosphere so that the sheet resistance of ITO transparent electrode layer 7 was reduced. The sheet resistance of ITO transparent electrode layer 7 was reduced to 11 Ω/□ after the second annealing.

Here, the thickness of transparent electrode layer 7 is not restricted in a particular range. If the thickness is made to small, however, the sheet resistance increases and then the operation voltage of the light-emitting device is liable to increase. If transparent electrode layer 7 is made too thick, on the other hand, the optical output is decreased due to light absorption of transparent electrode layer 7 though the operation voltage of the light-emitting device can be decreased. In the light-emitting device according to the present invention, therefore, the thickness of transparent electrode layer 7 preferably has a thickness in a range of 120 nm to 340 nm.

Transparent electrode layer 7 was etched by using a well-known photolithography method so as to remove a partial region thereof In the region where transparent electrode layer 7 was partially removed, etching was further conducted by using the photolithography method so that p-type semiconductor layer 12, p-type clad layer 14 and active layer 10 were partially removed by the etching so as to expose a partial area of n-type semiconductor layer 9.

Thereafter, a p-side electrode pad 6, a p-side branch electrode 4, an n-side electrode pad 5, and an n-side branch electrode 3 consisting of Ni(100 nm thick)/Pt(50 nm thick)/Au(500 nm thick) were formed by utilizing the photolithography method, electron beam evaporation and a well-known lift-off method. Here, from the viewpoint of the accuracy of the photolithography and the light absorption due to the electrodes, the width of each of the p-side and n-side branch electrodes is set in a range of 4 μm to 8 μm. Incidentally, p-side branch electrode 4 is preferably formed inward more than about 15 μm from the long side of rectangle current diffusion layer 7.

Etching was further conducted using the photolithography so as to form inclined surfaces on the side surfaces of n-type semiconductor layer 9. In this Embodiment 1, the inclination angle of the side surface of n-type semiconductor layer 9 was set to 40 degrees with respect to a plane parallel to the layer. With an effect of the inclined side surfaces, it is possible to enhance the light extraction efficiency around the peripheral regions of the light-emitting device.

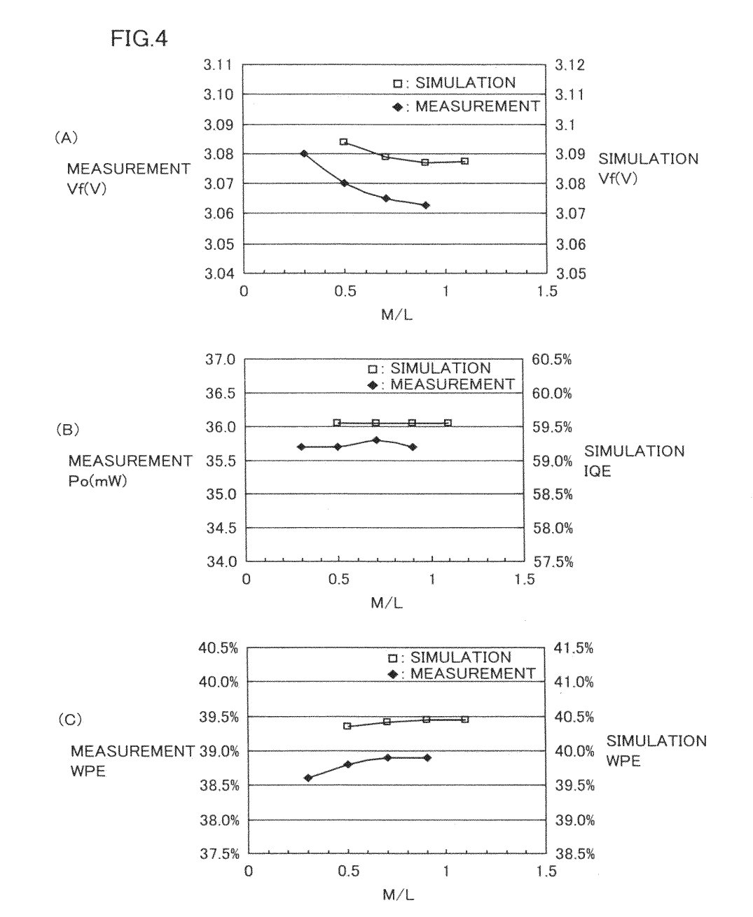

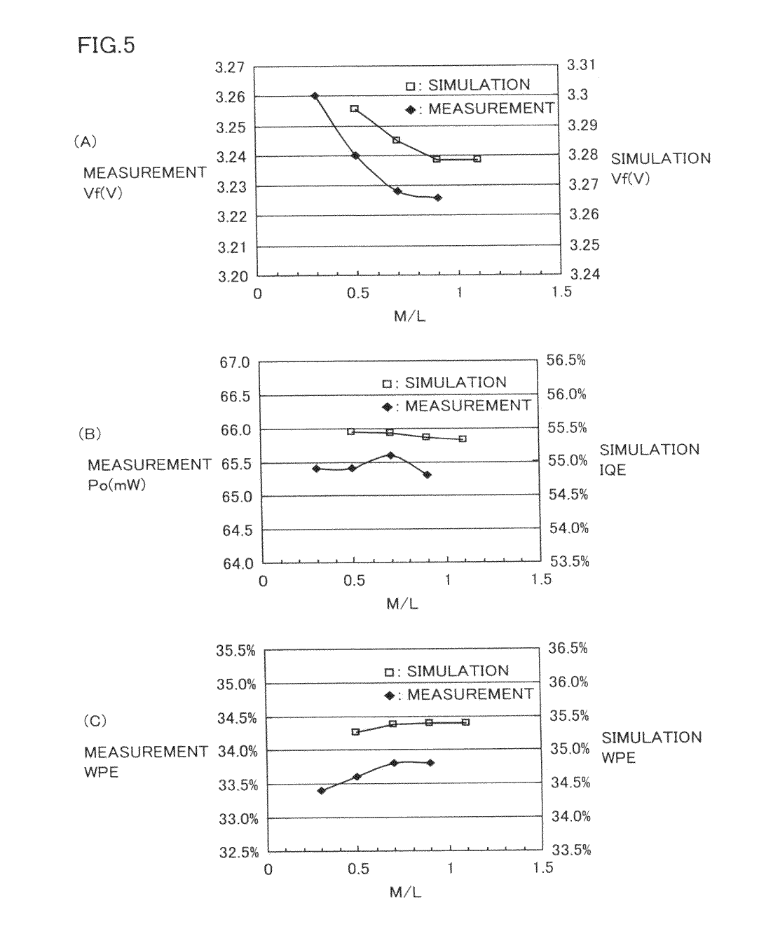

In this Embodiment 1 as explained above, there was obtained the semiconductor light-emitting device of a rectangle shape having a long side (X) of 550 μm and a short side (Y) of 280 μm. Incidentally, as shown in FIG. 3(A), the ratio of M/L was set to 0.9 in this Embodiment, where M represents the distance between the branch electrodes and L represents the distance between the centers of the p-side and n-side electrode pads. Various properties of the light-emitting device according to this Embodiment 1 are shown in Table 1 to Table 3 and FIG. 4 to FIG. 6.

TABLE 1
Operation Current 30 mA

| | | | | Comparative |
|---|---|---|---|---|
| | Embodiment 1 | Embodiment 2 | Embodiment 3 | Example 1 |
| M/L | 0.9 | 0.7 | 0.5 | 0.3 |
| Vf(V) | 3.063 | 3.065 | 3.070 | 3.080 |
| Po(mW) | 35.70 | 35.80 | 35.70 | 35.70 |
| WPE | 0.389 | 0.389 | 0.388 | 0.386 |

TABLE 2
Operation Current 60 mA

| | | | | Comparative |
|---|---|---|---|---|
| | Embodiment 1 | Embodiment 2 | Embodiment 3 | Example 1 |
| M/L | 0.9 | 0.7 | 0.5 | 0.3 |
| Vf(V) | 3.226 | 3.228 | 3.240 | 3.260 |
| Po(mW) | 65.34 | 65.56 | 65.41 | 65.36 |
| WPE | 0.338 | 0.338 | 0.336 | 0.334 |

TABLE 3
Operation Current 100 mA

| | | | | Comparative |
|---|---|---|---|---|
| | Embodiment 1 | Embodiment 2 | Embodiment 3 | Example 1 |
| M/L | 0.9 | 0.7 | 0.5 | 0.3 |
| Vf(V) | 3.392 | 3.397 | 3.417 | 3.443 |
| Po(mW) | 125.05 | 125.64 | 125.21 | 125.04 |
| WPE | 0.369 | 0.370 | 0.366 | 0.363 |

Table 1 to Table 3 show the various properties of the light-emitting devices in the case of the operation currents of 30 mA, 60 mA and 100 mA respectively and the graphs of FIG. 4 to FIG. 6 also show the various properties of the light-emitting devices in the case of the operation currents of 30 mA, 60 mA and 100 mA respectively. In these tables and graphs, Vf denotes the operation voltage (V), Po denotes the optical output (mW), WPE (wall plug efficiency) denotes the power efficiency (%), and IQE denotes the internal quantum efficiency. In the graphs, each black square mark and each white square mark show a measured property value and a simulated property value of the light-emitting device, respectively.

### Embodiment 2

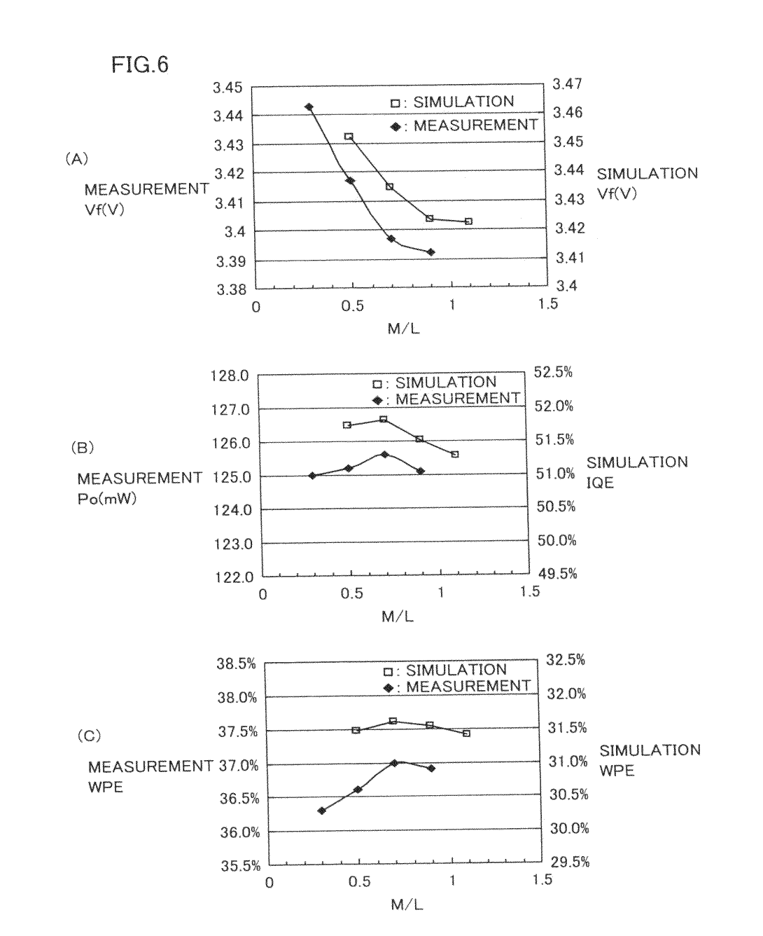

A light-emitting device according to Embodiment 2 of the present invention is schematically shown in a plan view of FIG. 3(B). The light-emitting device of this Embodiment 2 is different from Embodiment 1 only in that the ratio of M/L was reduced to 0.7, where M represents the distance between the branch electrodes and L represents the distance between the centers of the p-side and n-side electrodes pads. The change of the M/L value in the case of Embodiments 1 and 2 can clearly be seen in comparison between FIG. 3(A) and FIG. 3(B). As clearly seen in FIGS. 6(B) and 6(C), optical output Po (mW) and power efficiency WPE (%) of the light-emitting device of Embodiment 2 (M/L=0.7) are highest in the case that the light-emitting device is operated with current of 100 mA (current density>90 A/cm²; current injection area: 1.10×10⁻³cm²).

### Embodiment 3

A light-emitting device according to Embodiment 3 of the present invention is schematically shown in a plan view of FIG. 3(C). The light-emitting device of this Embodiment 3 is different from the other Embodiments only in that the ratio of M/L was further reduced to 0.5, where M represents the distance between the branch electrodes and L represents the distance between the centers of the p-side and n-side electrodes pads.

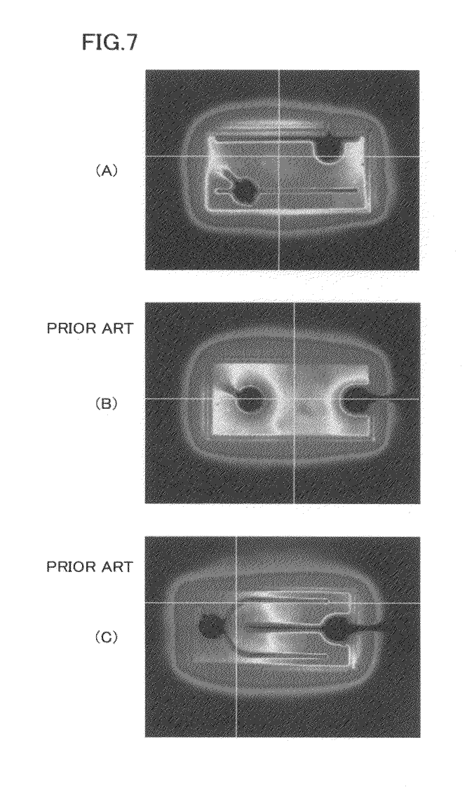

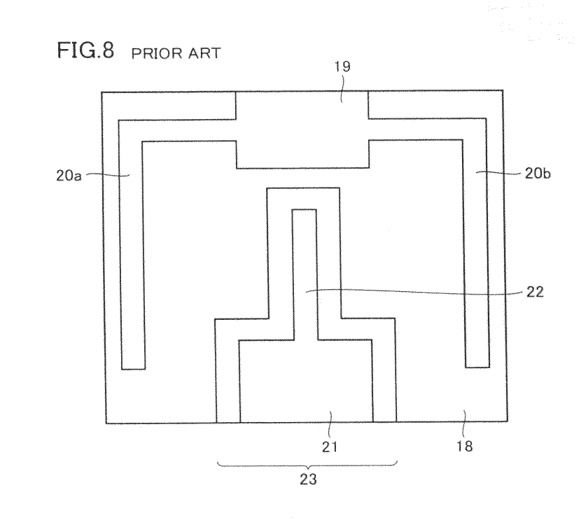

FIG. 7 shows photographs of light emission states of the light-emitting devices taken by a CCD camera (HAMAMATU C8000-20). Although the photographs attached hereto are shown as grayscale images, the original photographs are color images in which red, orange, yellow, green, powder blue, blue, and navy blue having different light wavelengths sequentially appear depending on an area emitting high intensity light to an area emitting low intensity light. When such a color photograph is converted to a black-and-white photograph, an area of green having an intermediate wavelength is shown brightest, and an area having a color toward red having a longer wavelength or toward navy blue having a shorter wavelength is shown darker.

In each black-and-white photograph in FIG. 7, within the upper surface area of the rectangle light-emitting device, the dark area corresponds to an area of red or orange indicating a high light intensity and the relatively bright area corresponds to an area of yellow or green indicating a relatively low light intensity (however, the electrode pad areas are blue). In the outside of the upper surface area of the rectangle light-emitting device, on the other hand, areas of red and orange do not exist and the dark area corresponds to an area of blue or navy blue.

In FIG. 7, (A) shows a light emission state of the light-emitting device according to Embodiment 3, (B) shows a light emission state of the light-emitting device according to Japanese Patent Laying-Open No. 2009-246275, and (C) shows a light emission state of the light-emitting device according to Japanese Patent Laying-Open No. 2009-253056. In this FIG. 7, (A) shows the emission state at a high current density of 136 A/cm² (injection current 150 mA; injection area 1.10×10⁻³ cm²), (B) shows the emission state with the injection current of 150 mA and the injection area of 1.17×10⁻³ cm², and (C) shows the emission state with the injection current of 150 mA and the injection area of 1.12×10⁻³ cm².

In the light-emitting device of Embodiment 3 of the present invention as shown in FIG. 7(A), the dark area corresponding to red or orange spreads widely on the upper surface of the device, and thus it is understood that the wide area emits light at high intensity. In the light-emitting device according to Japanese Patent Laying-Open No. 2009-246275 as shown in FIG. 7(B), on the other hand, the relatively bright area corresponding to yellow or green spreads widely on the upper surface of the device, and thus it is understood that the wide area emits light at low intensity. Further, in the light-emitting device according to Japanese Patent Laying-Open No. 2009-253056 as shown in FIG. 7(C), transition from the dark area corresponding to red or orange to the relatively bright area corresponding to yellow or green can be seen on the upper surface of the device, and thus it is understood that the intensity of light emitted from the upper surface of the device is very non-uniform depending on the areas.

### COMPARATIVE EXAMPLE 1

A light-emitting device according to Comparative Example 1 is schematically shown in a plan view of FIG. 3(D). The light-emitting device of this Comparative Example 1 is different from the above-described Embodiments only in that the ratio of M/L is further reduced to 0.3 by providing the p-side and n-side electrode pads at the diagonal positions (L=Lₘₐₓ) of the light-emitting device chip.

As shown in Table 1 to Table 3 and FIG. 4 to FIG. 6, it is understood that the light-emitting device according to Comparative Example 1 has the highest operation voltage Vf(V) and the lowest power efficiency WPE(%) as compared to the devices of the Embodiments at any of the operation currents of 30 mA, 60 mA and 100 mA.

### SUMMARY

In summary, as shown in Table 1 to Table 3, the ratios of M/L were set to 0.9, 0.7, 0.5 and 0.3 in the light-emitting devices of Embodiments 1, 2 and 3 and Comparative Example 1 respectively, where M represents the distance between the p-side and n-side branch electrodes and L represents the distance between the centers of p-side and n-side electrode pads.

Before the light-emitting devices of the Embodiments and Comparative Example were actually formed, simulations regarding operation voltage Vf(V), internal quantum efficiency IQE(%) and power efficiency WPE(%) were conducted at the operation currents of 30 mA, 60 mA and 100 mA under the conditions of M/L values of 0.5, 0.7, 0.9, and 1.1. As mentioned before, the results of simulations are also shown by white square marks in the graphs of FIG. 4 to FIG. 6.

Further, to examine the facts, the light-emitting devices of Embodiments 1 to 3 and Comparative Example 1 were formed and operation voltage Vf(V), optical output Po(mA) and power efficiency WPE(%) were actually measured at the operation currents of 30 mA, 60 mA and 100 mA. These measured results are also shown by the black square marks in the graphs of FIG. 4 to FIG. 6.

It should be noted that the optical output is evaluated by internal quantum efficiency IQE in the simulation while it is evaluated by the total radiant flux measured using an integral sphere in the actual measurement. It is understood that while the measured evaluation value and the simulated evaluation value are different regarding each evaluation item, those evaluation values regarding each evaluation item show similar dependency on M/L.

As seen in Table 1 to Table 3 and FIG. 4 to FIG. 6, it is also understood that operation voltage Vf depends on distance L between the electrode pads in each of Embodiment 1 to 3 and Comparative Example 1 and its dependency is most significant in the case of the high injection current (100 mA). Then, it is understood that 0.6<M/L<0.8 is a preferable range and M/L is most preferably about 0.7 in the case of the injection current of 100 mA (current density>90A/cm²; injection area 1.10×10⁻³ cm²).

As seen in FIG. 7(A) referred to in the above, in the case of M/L in a preferable range, it is understood that the light-emitting device shows good light emission uniformity even at the high operation current density of 136 A/cm² (injection current 150 mA; injection area 1.10×10⁻³ cm²).

Incidentally, while it has been explained in Embodiments 1 to 3 that both the electrode pads are positioned symmetrically with respect to the center of the light-emitting device, those pads are not restricted to be positioned such symmetrical positions. Further, it is not necessary that the p-side and n-side branch electrodes are extended though the centers of the p-side and n-side electrode pads respectively. In the case that the sheet resistance of the transparent electrode layer is significantly greater than that of the n-type semiconductor layer, it is preferable to position the p-side branch electrode in the interior near the central area of the light-emitting device.

The nitride semiconductor light-emitting device according to the present invention can preferably be used for the LED illumination, the backlight of liquid crystal TV and so forth.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride semiconductor light-emitting device comprising at least one n-type semiconductor layer, an active layer and at least one p-type semiconductor layer in this order within a rectangle nitride semiconductor region on an upper surface of a substrate, wherein
said n-type semiconductor layer has a partial exposed area formed by etching from the p-type semiconductor layer side,
a current diffusion layer is provided on said p-type semiconductor layer,
a p-side electrode pad and a p-side branch electrode extending linearly therefrom are provided on said current diffusion layer,
an n-side electrode pad and an n-side branch electrode extending linearly therefrom are provided on said partial exposed area of said n-type semiconductor layer,
said p-side branch electrode and said n-side branch electrode extend parallel to each other along two opposite sides of said rectangle nitride semiconductor region, and
conditions of 0.3<M/L<1.1 and L<Lₘₐₓ are satisfied, where L represents a distance between the center of said p-side electrode pad and the center of said n-side electrode pad, M represents a distance between said p-side branch electrode and said n-side branch electrode parallel to each other, and Lₘₐₓ represents a distance between the center of said p-side electrode pad and the center of said n-side electrode pad when they are formed at diagonal positions of said rectangle nitride semiconductor region.

2. The nitride semiconductor light-emitting device according to claim 1, wherein a condition of 0.6<M/L<0.8 is satisfied.

3. The nitride semiconductor light-emitting device according to claim 1, wherein a condition of M/L=0.7 is satisfied.

4. The nitride semiconductor light-emitting device according to claim 1, wherein said p-side branch electrode is formed near a side of said rectangle nitride semiconductor region and on the inside more than 15 μm from said side.

5. The nitride semiconductor light-emitting device according to claim 1, wherein said p-side branch electrode has a width in a range of 4 μm to 8 μm.

6. The nitride semiconductor light-emitting device according to claim 1, wherein said current diffusion layer has a thickness in a range of 120 μm to 340 μm.

7. The nitride semiconductor light-emitting device according to claim 1 wherein a side surface of said n-type semiconductor layer has an inclination angle less than 90 degrees with respect to a plane parallel to the layer.

8. The nitride semiconductor light-emitting device according to claim 7, wherein said inclination angle is in a range of 20 degrees to 80 degrees.

9. The nitride semiconductor light-emitting device according to claim 8, wherein said inclination angle is in a range of 25 degrees to 50 degrees.

10. The nitride semiconductor light-emitting device according to claim 9, wherein said inclination angle is 30 degrees.

11. The nitride semiconductor light-emitting device according to claim 1, wherein said upper surface of the substrate has a periodic uneven structure.
